(19) United States
(12) Patent Application Publication
(10) Pub. No.: US 2025/0132265 A1
(43) Pub. Date: Apr. 24, 2025

(54) ALIGNMENT MARKERS FOR WAFER BONDING AND ASSOCIATED SYSTEMS AND METHODS

(71) Applicant: Micron Technology, Inc., Boise, ID (US)

(72) Inventors: Kyle K. Kirby, Eagle, ID (US); Mark Fischer, Boise, ID (US)

(21) Appl. No.: 18/789,128

(22) Filed: Jul. 30, 2024

Related U.S. Application Data
(60) Provisional application No. 63/544,753, filed on Oct. 18, 2023.

(51) Int. Cl. H01L 23/544; H01L 23/498

(52) U.S. Cl. CPC H01L 23/544; H01L 23/49838; H01L 2223/54426

(57) ABSTRACT

Semiconductor devices, and related systems and methods, are disclosed herein. In some embodiments, the semiconductor device includes a first wafer having a front surface and a back surface opposite the front surface, and a second wafer having upper surface coupled to the back surface of the first wafer. The first wafer can also include one or more first alignment features. Each of the first alignment feature(s) can include a transparent material extending from the front surface to the back surface, thereby forming a window through the first wafer, allowing the location of conductive features on the front surface to be determined from the back surface using optical measurements. The second wafer can include one or more second alignment features that are positioned within a longitudinal footprint of a corresponding one of the first alignment features.

### CROSS-REFERENCE TO RELATED APPLICATION(S)

The present application claims priority to U.S. Provisional Patent Application No. 63/544,753, filed Oct. 18, 2023, the disclosure of which is incorporated herein by reference in its entirety.

### TECHNICAL FIELD

The present technology is generally related to wafer bonding, and more specifically to forming optically visible alignment markers for wafer-to-wafer bonding.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk and then stacked. For example, multiple wafers can be stacked while manufacturing a single die, then multiple dies can be stacked on a support substrate (e.g., a printed circuit board (PCB) or other suitable substrates). While stacking the wafers, dies, and/or active components, marks are typically used to help identify the location of bonding structures and aligned the stacked components.

### BRIEF DESCRIPTION OF THE DRAWINGS

FIG. 1 is a partially schematic cross-sectional view of a semiconductor device with stacked wafers configured in accordance with some embodiments of the present technology.

FIGS. 2A-2F are partially schematic cross-sectional views of a semiconductor device at various stages of manufacturing in accordance with some embodiments of the present technology.

FIG. 2G is a partially schematic top view of the semiconductor device of FIGS. 2A-2F after stacking two wafers in accordance with some embodiments of the present technology.

FIGS. 2H and 2I are partially schematic cross-sectional views of the semiconductor device of FIGS. 2A-2G at various further stages of manufacturing in accordance with some embodiments of the present technology.

FIG. 3 is a flow diagram of a process for manufacturing semiconductor devices in accordance with some embodiments of the present technology.

FIGS. 4A and 4B are a partially schematic cross-sectional view and a partially schematic top view, respectively, of alignment features for stacking semiconductor components in accordance with further embodiments of the present technology.

FIGS. 5A and 5B are a partially schematic cross-sectional view and a partially schematic top view, respectively, of alignment features for stacking semiconductor components in accordance with further embodiments of the present technology.

FIGS. 6A and 6B are a partially schematic cross-sectional view and a partially schematic top view, respectively, of alignment features for stacking semiconductor components in accordance with further embodiments of the present technology.

FIGS. 7A and 7B are a partially schematic cross-sectional view and a partially schematic top view, respectively, of alignment features for stacking semiconductor components in accordance with further embodiments of the present technology.

FIGS. 8A and 8B are a partially schematic cross-sectional view and a partially schematic top view, respectively, of alignment features for stacking semiconductor components in accordance with further embodiments of the present technology.

FIGS. 9A and 9B are a partially schematic cross-sectional view and a partially schematic top view, respectively, of alignment features for stacking semiconductor components in accordance with further embodiments of the present technology.

FIG. 10 is a schematic view of a system that includes a semiconductor die assembly configured in accordance with embodiments of the present technology.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

Specific details of several embodiments of semiconductor wafers, semiconductor assemblies, and associated systems and methods are described below. The term “semiconductor device or die” generally refers to a solid-state device that includes one or more semiconductor materials. Examples of semiconductor devices include logic devices, memory devices, controllers, or microprocessors (e.g., central processing unit (CPU), graphics processing unit (GPU)), among others. Such semiconductor devices may include integrated circuits or components, data storage elements, processing components, and/or other features manufactured on semiconductor substrates. Further, the term “semiconductor device or die” can refer to a finished device or to an assembly or other structure at various stages of processing before becoming a finished functional device. Depending upon the context in which it is used, the term “substrate” can refer to a wafer-level substrate or to a singulated, die-level substrate. Also, a substrate may include a semiconductor wafer, a package support substrate, an interposer, a semiconductor device or die, or the like. A person having ordinary skill in the relevant art will recognize that suitable steps of the methods described herein can be performed at the wafer level or at the die level.

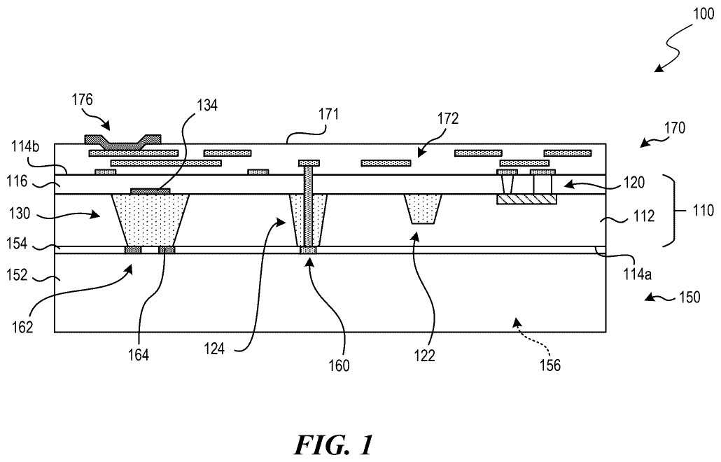

Further, unless the context indicates otherwise, structures disclosed herein can be formed using conventional semiconductor-manufacturing techniques. Materials can be deposited, for example, using chemical vapor deposition (CVD), physical vapor deposition (PVD), atomic layer deposition (ALD), spin coating, plating, and/or other suitable techniques. Similarly, materials can be removed, for example, using plasma etching, wet etching, chemical-mechanical planarization, or other suitable techniques. Some of the techniques may be combined with photolithography processes. A person skilled in the relevant art will also understand that the technology may have additional embodiments and that the technology may be practiced without several of the details of the embodiments described herein with reference to FIGS. 1-8.

In typical semiconductor device manufacturing, wafer-to-wafer bonding requires an infrared sensor to take measurements through one or more wafers to identify features on each of the wafers. The infrared images can then be used to align critical features (e.g., conductive structures, high aspect ratio contacts, interconnect structures, and/or conductive pads) between the wafers to establish conductive route lines within a stacked device. However, infrared images are typically blurry (e.g., due to scattering in each of the wafers being imaged), which imposes a limit on the accuracy of the alignment that can be achieved. As the critical features that need to be aligned continue to shrink, the blurriness (and resulting inaccuracies) can undermine the wafer-to-wafer bonding process, resulting in increased costs due to wasted wafers and/or realignment processes.

Methods for forming semiconductor devices with improved alignment, the resulting semiconductor devices, and related systems and methods, are disclosed herein. In some embodiments, the semiconductor device (sometimes also referred to herein as a “semiconductor device assembly”) includes a first wafer having a front surface and a back surface opposite the front surface, and a second wafer having an upper surface coupled to the back surface of the first wafer. The first wafer also includes various electrical components, such as one or more gates, passive electrical elements, and/or signal trenches extending from the front surface to the back surface. Each of the signal trenches can include a conductive structure that establishes a signal route line through the first wafer. The first wafer can also include one or more first alignment features, each of which includes a generally transparent material extending from the front surface to the back surface. As a result, each of the first alignment feature(s) forms one or more windows between the front surface and the back surface that allow an alignment process to determine the location of features of the first wafer from the back side of the first wafer.

Similar to the first wafer, the second wafer can include various electrical components, such as one or more bond pads (also referred to herein as “conductive pads”) at the upper surface, passive and/or active electrical components formed within the second wafer, and/or array circuitry formed within the second wafer. Each of the bond pads can be coupled to a corresponding one of the conductive structures in the first wafer, thereby establishing a signal route line between the first and second wafers. Further, the second wafer can also include one or more second alignment features that are positioned within a longitudinal footprint of a corresponding one of the first alignment feature(s). As discussed in more detail below, the first and second alignment features can be used to align corresponding features of the first and second wafers during wafer-to-wafer bonding. Further, because the window created by the first alignment feature allows the position of features of the first wafer to be more easily identified from the back side, the first and second alignment features allow the first and second wafers to be aligned using optical imaging rather than infrared imaging.

In some embodiments, each of the first alignment feature(s) includes one or more first alignment marks and each of the second alignment feature(s) includes one or more second alignment marks. In some such embodiments, the first and second alignment marks do not vertically overlap when the first and second wafers are appropriately aligned. Instead, for example, they can create an alignment pattern that allows the alignment to be easily verified.

In some embodiments, the second alignment marks in the second alignment feature(s) are visible in the windows created by the first alignment feature(s) after the first and second wafers are stacked. In other embodiments, the second alignment marks in the second alignment feature(s) are not vertically aligned with the windows and are not optically visible. In some such embodiments, the alignment of the first and second wafers can be confirmed via infrared measurements (e.g., using infrared to confirm alignment after using optical measurements to align and stack the wafers).

In some embodiments, the semiconductor device further includes a third wafer (e.g., an interposer wafer) coupled to the front surface of the first wafer. The third wafer can include one or more metallization layers that establish signal route lines between electrical components in the first wafer. For example, each of the conductive structures, gates, and/or passive components in the first wafer can be electrically coupled to one or more of the one or more metallization layers in the third wafer and/or interconnected therein.

Forming semiconductor devices of the type described herein can include various stages of wafer-level semiconductor production and/or wafer-to-wafer bonding processes. For example, in some embodiments, a method for forming a semiconductor device of the type disclosed herein includes forming one or more conductive structures and a first alignment feature at a first surface of a first wafer using various front-end-of-line (FEOL) processes. The method can then include attaching the first wafer to a carrier wafer and removing material removed from a second surface of the first wafer to thin the first wafer. Thinning the first wafer can expose a lower surface of at least one of the conductive structures and/or a lower surface of the first alignment feature. The method can then include aligning the first alignment feature on the first wafer with a second alignment feature formed on an upper surface of a second wafer, then stacking the second surface of the first wafer on the upper surface of the second wafer.

Because the lower surface of the first alignment feature is exposed on the second surface of the first wafer, the first alignment feature can form a window through the first wafer that allows an alignment marker formed on the first surface to be visible from the second surface. Accordingly, the alignment of the first and second alignment features can be based on optical measurements of the first and second alignment features, rather than infrared measurements. The optical measurements can provide more clarity and/or more precise measurements of the location of the first and second alignment features, allowing the first and second wafers to be closely aligned (e.g., with a margin of error on the nanometer scale or less).

Additional details on the semiconductor devices, methods for forming the same, and associated systems and methods are set out below. For ease of reference, the semiconductor assemblies (and their components) are sometimes described herein with reference to front and back, top and bottom, upper and lower, upwards and downwards, and/or horizontal plane, x-y plane, vertical, or z-direction relative to the spatial orientation of the embodiments shown in the figures. It is to be understood, however, that the semiconductor assemblies (and their components) can be moved to, and used in, different spatial orientations without changing the structure and/or function of the disclosed embodiments of the present technology.

Further, although the alignment features disclosed herein are primarily discussed in the context of wafer-to-wafer bonding, one of skill in the art will understand that the scope of the technology is not so limited. For example, the alignment features can also be deployed in various other settings (e.g., in stacking die packages on a substrate, stacking dies on top of each other, and/or in any other suitable setting) to improve the alignment of the stacked structures.

Still further, several aspects of the alignment features disclosed herein are described with reference to generally transparent, transparent, or semitransparent materials. As used herein, transparent and/or semitransparent refer to an optical quality of a material that allows light of one or more frequencies or one or more ranges of frequencies (e.g., visible frequencies, ultraviolet frequencies, infrared frequencies, microwave frequencies, etc.) to pass through the material at least partially unobstructed, allowing for vision through the transparent and/or semitransparent (e.g., such that an optical sensor can see through the transparent and/or semitransparent).

FIG. 1 is a partially schematic cross-sectional view of a portion of a semiconductor device 100 configured in accordance with some embodiments of the present technology. The semiconductor device 100 (“device 100”) includes a stack of wafer components including a first wafer 110, a second wafer 150 coupled to a lower surface 114a of the first wafer 110, and a third wafer 170 coupled to an upper surface 114b of the first wafer 110. Each of the first, second, and third wafers 110, 150, 170 can include various semiconductor components (active and passive) that form a portion (or all) of a semiconductor die and/or another suitable component.

In the illustrated embodiment, the first wafer 110 is a complementary metal-oxide-semiconductor (CMOS) wafer that includes a base substrate 112 and one or more dielectric layers 116 formed on the base substrate. Further, the first wafer 110 includes one or more gates 120 (one illustrated schematically in FIG. 1, e.g., a CMOS gate) and one or more isolation trenches 122 (one illustrated in FIG. 1) positioned between each of the gates 120 the other electrical components on the first wafer 110. For example, in the embodiment illustrated in FIG. 1, the first wafer 110 further includes a signal trench 124 with a conductive structure formed therein (e.g., a high aspect ratio conductive contact, a through substrate via, an interconnect structure, and/or the like). In this embodiment, the isolation trench 122 is positioned between the gate 120 and the signal trench 124.

Similar to the first wafer 110, the second wafer 150 includes a base substrate 152 and one or more insulation layers 154 (e.g., dielectric layers and/or any other suitable insulators) formed on the base substrate 152. The second wafer 150 also includes one or more bond pads 160 (one illustrated in FIG. 1) positioned on the base substrate 152 and in contact with conductive features on the lower surface 114a of the first wafer 110. For example, in the illustrated embodiment, the bond pad 160 is electrically coupled to the conductive structure in the signal trench 124 at the lower surface 114a, thereby establishing an electrical connection between the first and second wafers 110, 150. The electrical connections can allow various components of the first wafer 110 (e.g., the gate 120) to communicate with internal electronics 156 in the second wafer 150 (e.g., array circuitry, capacitors, resistors, and/or any other suitable components). The third wafer 170 can include one or more metallization layers 172 that establish signal routing lines to further connect various components of the device 100. Additionally, as further illustrated in FIG. 1, the third wafer 170 can include a bond pad 176 formed on an uppermost surface 171 of the third wafer 170. The bond pad 176 (sometimes also referred to herein as a “package interconnect,” a “package terminal,” and/or the like) can allow the device 100 to be coupled to various external components, such as additional semiconductor devices (e.g., in die stacks), a package support substrate such as a PCB, and/or any other suitable component.

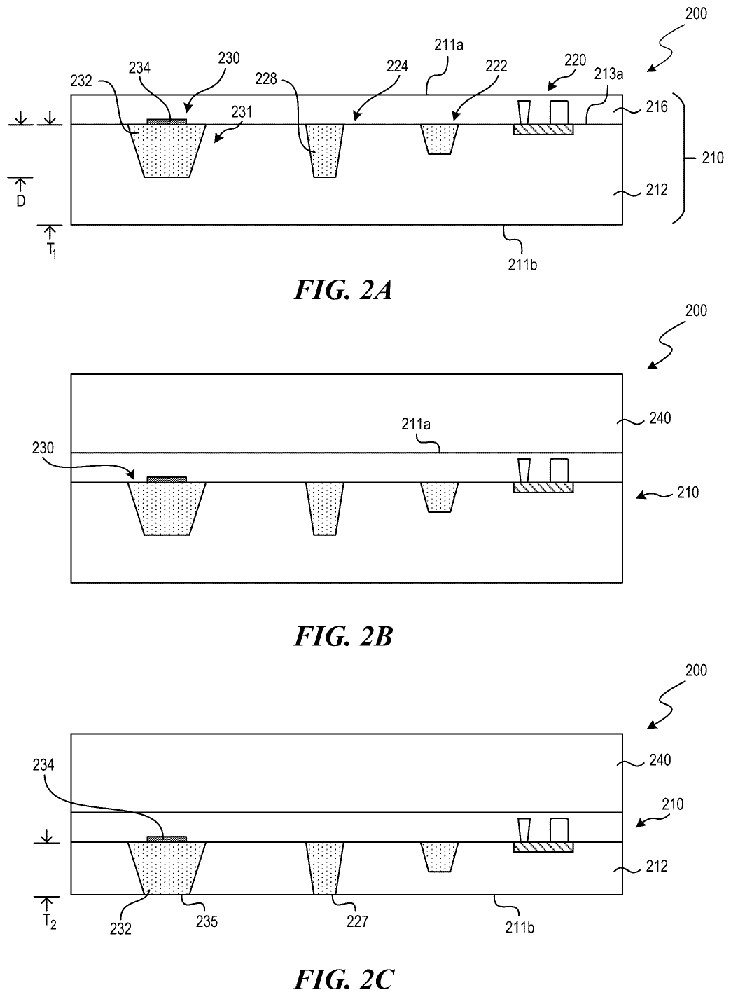

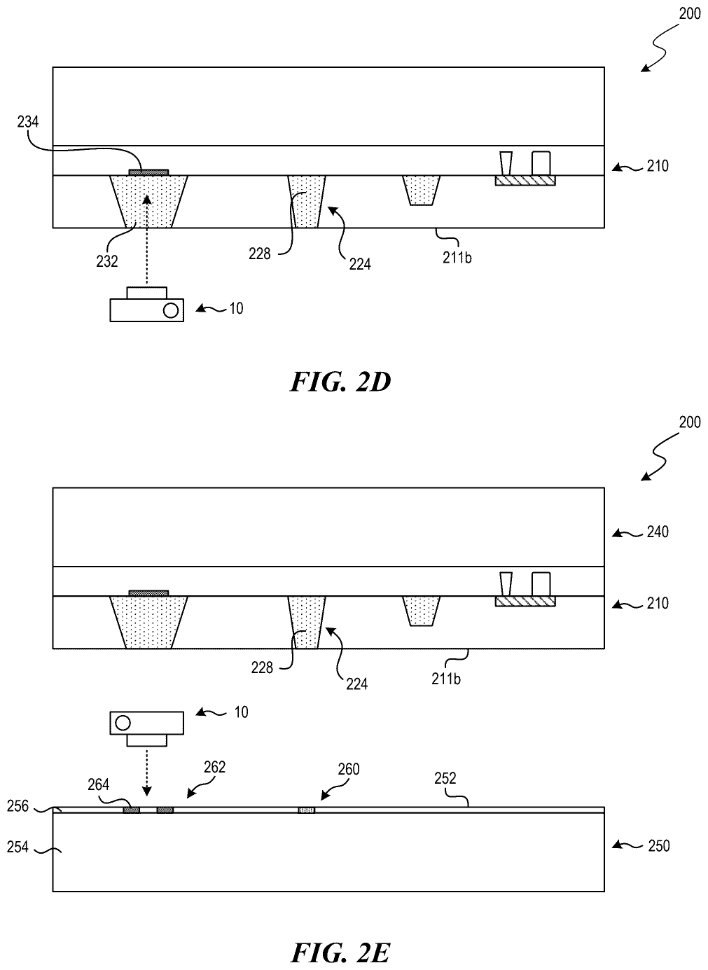

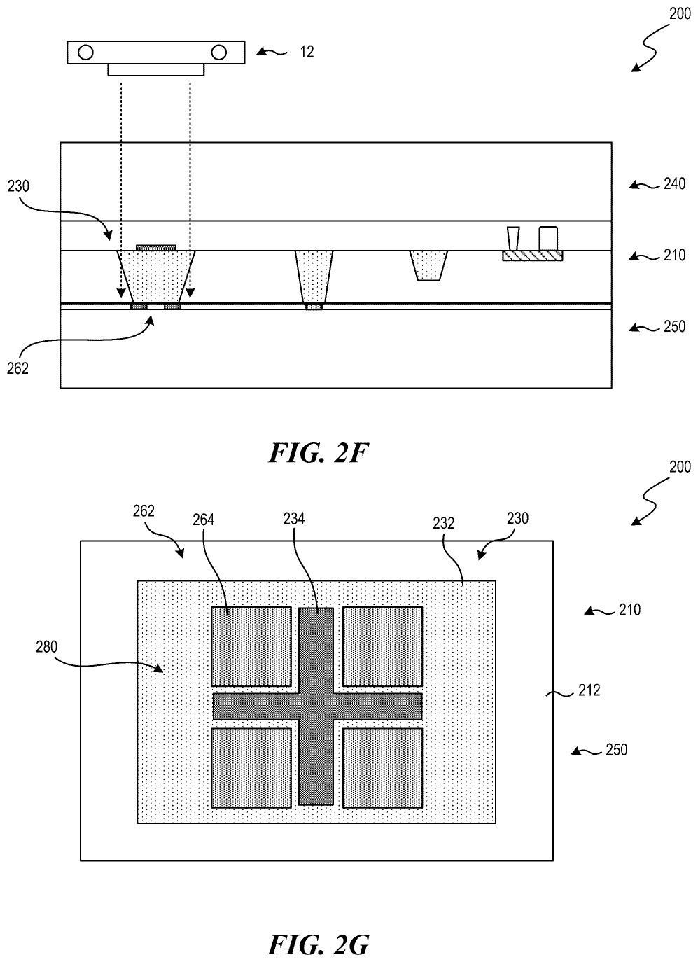

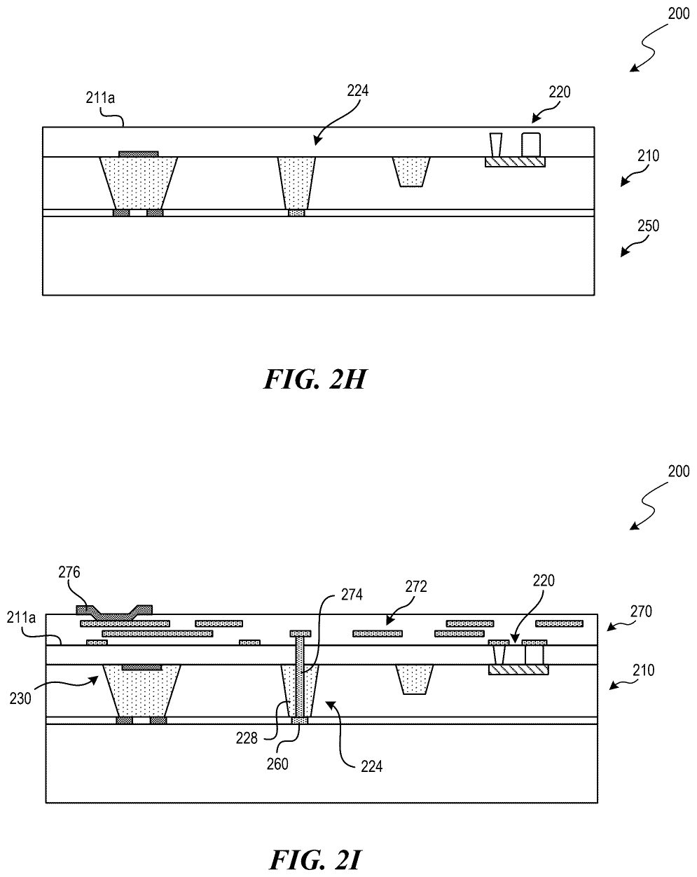

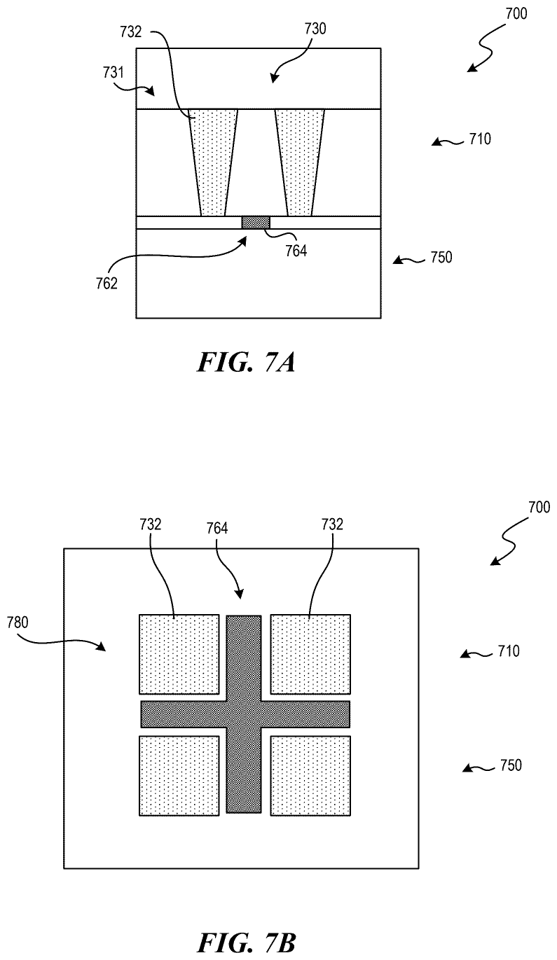

As semiconductor devices continue to shrink and demands for electrical functionality continue to increase, the size of the internal components of the device 100 (e.g., the signal trench 124 and/or the size of the conductive structure within the signal trench 124, the bond pad 160, and the like) also continue to shrink. As a result, the alignment between the first and second wafers 110, 150 becomes critical to ensure that corresponding components are adequately aligned to form electrical and/or thermal connections within the device 100. As further illustrated in FIG. 1, device 100 can also include various alignment features to aid in aligning the first and second wafers 110, 150, the. For example, in the illustrated embodiment, the first wafer 110 includes one or more alignment sockets 130 (one illustrated in FIG. 1, sometimes also referred to herein as an “alignment feature”) while the second wafer 150 includes one or more alignment features 162 (one illustrated in FIG. 1) that each include one or more second alignment marks 164 (two illustrated in FIG. 1). As discussed in more detail below, the alignment socket(s) 130 can provide an optical window through the first wafer 110 to utilize the alignment feature(s) 162 with relatively high resolution (e.g., as compared to locating the marks using infrared imaging through the base substrate 112). In some embodiments, the alignment socket(s) 130 include additional features that help guide the alignment, such as one or more first alignment marks 134 that form a pattern with the second alignment marks 164 when the first and second wafers 110, 150 are correctly aligned. In some embodiments, each of the alignment sockets 130 includes a plurality of trenches that are sized such that when one of the alignment marks 164 is visible through each of the alignment sockets 130, the first and second wafers 110, 150 are correctly aligned (e.g., see FIGS. 7A and 7B, described below). In some embodiments, a first pair of the alignment socket(s) 130 and the alignment feature(s) 162 is used to align the first and second wafers 110, 150 during a stacking process and a second pair of the alignment socket(s) 130 and the alignment feature(s) 162 is used to confirm the alignment after the first and second wafers 110, 150 are stacked. Additional details on various suitable wafer-level processes using the alignment features are set out below with reference to FIGS. 2A-7B.

FIGS. 2A-2I are partially schematic views of a semiconductor device 200 at various stages of manufacturing in accordance with some embodiments of the present technology. FIG. 2A illustrates the semiconductor device 200 (“device 200”) after various front-end-of-line (FEOL) processes have formed various electrical components on a first wafer 210. In the illustrated embodiment, the first wafer 210 includes a base substrate 212 (e.g., a silicon substrate) and one or more insulation layers 216 (e.g., dielectric layers and/or any other suitable layers) formed on the base substrate 212. In the illustrated embodiment, the FEOL processes formed a gate 220, an isolation trench 222, a signal trench 224, and a first alignment feature 230 at a first side 211a (e.g., a front side, also referred to herein as a “first surface,” a “front surface,” and/or the like) of the first wafer 210. The gate 220 can be a CMOS gate and/or any other suitable gate. The isolation trench 222 includes an insulation material (e.g., a dielectric material) that is positioned between the gate 220 and the other electrical features on the first wafer 210 (e.g., the signal trench 224) to help insulate the gate 220 and/or prevent current leakage between the electrical components. Similar to the isolation trench 222, the signal trench 224 includes an insulation material 228 (e.g., a dielectric) that can have a conductive structure (e.g., a high aspect ratio contact) later formed therein.

The first alignment feature 230 includes a trench 231 filled with a generally transparent material 232 (or semitransparent material, referred to herein as a “transparent material’) and one or more first alignment marks 234 (one illustrated in the cross-section of FIG. 2A) formed on top of the transparent material 232 (e.g., at an upper surface 213a of the base substrate 212). The trench 231 can be formed by known FEOL processes. For example, the trench 231 can be formed contemporaneously with a trench for the signal trench 224 and/or the isolation trench 222. Further, in some embodiments, the insulation material 228 (and/or the insulation material in the isolation trench 222) can be an oxide-based dielectric. Oxide-based dielectrics are typically optically transparent materials and suitable for use in the first alignment feature 230. Accordingly, in some such embodiments, the trench 231 can be formed and filled contemporaneously with the formation of the signal trench 224 and/or the isolation trench 222. For example, the FEEL processes can include forming a first trench in the upper surface 213a of the base substrate 212 (and/or the first side 211a of the first wafer 210 more generally) that corresponds to the signal trench 224. At the same time (or sequentially), the FEOL processes can include forming a second trench in the upper surface 213a (and/or the first side 211a of the first wafer 210 more generally) that corresponds to the trench 231. The second trench can be spaced apart from the first trench by a known distance, allowing the alignment processes discussed below to later extrapolate from the position of the first alignment feature 230 to the position of the signal trench 224. The FEOL processes can then include filling the first and second trenches with an oxide-based material that is generally transparent. Additional processes can then form the first alignment marks 234 of the first alignment feature 230.

In various embodiments, the first alignment marks 234 can be formed from any suitable material that is optically different from the transparent material 232 (e.g., an opaque material, a different color, and/or not transparent). Purely by way of example, the first alignment marks 234 can be formed from a suitable metal (e.g., copper) plated into and/or on the transparent material 232 in a desired pattern. Additionally, or alternatively, the first alignment marks 234 can be formed from a suitable polymer that provides an optical distinction from the transparent material 232. As a result, when the back side of the base substrate 212 is thinned (e.g., as illustrated in FIG. 2C), the transparent material 232 provides a window through the base substrate 212 while the first alignment marks 234 provide an optically visible, known reference point. The known reference point can be used to align the first wafer 210 with one or more additional wafers and/or identify the location of electronic components on the first side 211a of the first wafer 210 from a second side 211b (e.g., a back side, also referred to herein as a “back surface,” a “second surface,” and/or the like) of the first wafer 210.

As further illustrated in FIG. 2A, the signal trench 224 and the first alignment feature 230 can extend to an intermediate depth D that is less than a first thickness T₁ of the base substrate 212 after the FEOL processes. The intermediate depth D can correspond to a final thickness of the base substrate 212 (e.g., as illustrated in FIG. 2C). As a result, the signal trench 224 and the first alignment feature 230 can be exposed by later thinning processes without also needing to be thinned and/or later removed.

FIG. 2B illustrates the device 200 after the first side 211a of the first wafer 210 is attached to a carrier wafer 240. The carrier wafer 240 can be a silicon substrate, oxide-based substrate, and/or any other suitable material that provides support to the first wafer 210 during further processing and/or helps transport the first wafer 210 between various manufacturing locations.

FIG. 2C illustrates the device 200 after the base substrate 212 is thinned from the second side 211b of the first wafer 210. In various embodiments, the base substrate 212 can be thinned through a mechanical grinding process, a chemical-mechanical planarization (CMP) process, a dry etch process, a wet etching process, and/or any other suitable process. The thinning process reduces the thickness of the base substrate 212 to a second thickness T₂ and exposes a lower surface 227 of the signal trench 224 and a lower surface 235 of the first alignment feature 230. As a result, for example, the first alignment marks 234 are visible through the transparent material 232 from the second side 211b of the first wafer 210.

FIGS. 2D and 2E illustrate the device 200 while aligning the first wafer 210 with a second wafer 250 (FIG. 2E) using the visibility of the first alignment marks 234. For example, as illustrated in FIG. 2D, an optical imaging element 10 can be positioned beneath the second side 211b of the first wafer 210 to measure (and/or record) a location of the first alignment marks 234 through the transparent material 232. Once measured and/or recorded, a manufacturing process can extrapolate from the first alignment marks 234 to any other suitable features on the first wafer 210, such as the location of the signal trench 224.

As illustrated in FIG. 2E, the optical element 10 can then be positioned above an upper surface 252 of the second wafer 250 to measure and/or record the position of a second alignment feature 262 formed thereon. In the illustrated embodiment, the second wafer 250 includes a base substrate 254 (e.g., a silicon substrate) and an insulation layer 256 formed over the base substrate 254. The second alignment feature 262 can include one or more second alignment marks 264 (two illustrated in FIG. 2E) formed in the insulation layer 256. Similar to the first alignment marks 234, the second alignment marks 264 can be formed from any suitable optically identifiable material, such as a metal (e.g., copper) that is patterned into openings in the insulation layer 256.

Once the optical element 10 measures and/or records the location of the second alignment marks 264, the manufacturing process can extrapolate from the second alignment marks 264 to the location of various other features of the second wafer 250, such as one or more bond pads 260 (one illustrated in FIG. 2E) formed in the insulation layer 256. The bond pad 260 facilitates an electrical connection between internal electronics in the second wafer 250 (e.g., array circuitry and/or any other suitable components). Further, the bond pad 260 can be visible within the signal trench 260, allowing a conductive structure to later be formed in the signal trench 224 to intercouple the first and second wafers 210, 250. Because the bond pad 260 and/or the signal trench 224 can have cross-sectional areas on the scale of square nanometers, there is almost no margin for error when aligning the first and second wafers 210, 250. The optical visibility of the first and second alignment marks 234, 264 (especially the first alignment marks 234) can improve the accuracy of the alignment (e.g., as compared to a process using only infrared imaging to identify alignment marks on the first wafer 210).

FIG. 2F illustrates the device 200 after the first and second wafers 210, 250 are aligned and stacked. Before bonding the first and second wafers 210, 250 together, the manufacturing process can double-check the alignment. In some embodiments, the manufacturing process can double-check the alignment using traditional techniques. For example, as illustrated in FIG. 2F, an infrared imaging device 12 can be positioned above the carrier wafer 240 to image the first and second alignment features 230, 262. The manufacturing process can use the image data from the imaging device 12 to confirm that the first and second alignment marks 234, 264 (FIG. 2E) are sufficiently aligned. In some embodiments, the carrier wafer 240 can be a generally transparent (or semitransparent) material. In such embodiments, the manufacturing process can double-check the alignment using image data from an optical measurement (e.g., image data from the optical element 10 of FIGS. 2D and 2E). In some embodiments, the carrier wafer 240 can include a generally transparent portion that is generally aligned with the first and second alignment features 230, 262. In such embodiments, the manufacturing process can double-check the alignment using image data from an optical measurement (e.g., image data from the optical element 10 of FIGS. 2D and 2E).

FIG. 2G is a top view of the device 200 providing a partially schematic illustration of the image data for when the first and second wafers 210, 250 are sufficiently aligned. For example, the first and second alignment features 230, 262 can form a pattern 280 that allows the alignment to be quickly checked. In particular, in the illustrated embodiment, the first alignment feature 230 includes a single first alignment mark 234 having a plus shape formed in the transparent material 232 while the second alignment feature 262 includes four second alignment marks 264. When the first and second wafers 210, 250 are sufficiently aligned, the four second alignment marks 264 fit into the corners of the first alignment mark 234 to form the pattern 280 illustrated in FIG. 2G. When the first and second wafers 210, 250 are not aligned, the misalignment in the pattern 280 can also help indicate what adjustments are necessary to align the first and second wafers 210, 250.

After double-checking the alignment, the manufacturing process can bond the first and second wafers 210, 250 together. In various embodiments, bonding the first and second wafers 210, 250 can include forming a metal-metal bond (e.g., via an annealing process) between conductive structures on the first wafer 210 and conductive structures on the second wafer 250, forming a hybrid bond between the first and second wafers 210, 250, a reflow process between one or more components on the first and second wafers 210, 250 and/or any other suitable process.

FIG. 2H illustrates the device 200 after the bond between the first and second wafers 210, 250 is complete and after the carrier wafer 240 (FIG. 2E) has been removed from the first side 211a of the first wafer 210. As illustrated in FIG. 2H, the removal of the carrier wafer 240 can expose the electrical features of the first wafer 210, such as the gate 220 and/or the signal trench 224, for various middle-of-line (MOL) processing stages and/or various back-end-of-line (BEOL) processing stages.

FIG. 2I illustrates the device 200 after various MOL and BEOL processing stages. As illustrated in FIG. 2I, the MOL processing stages (or first stages of the BEOL processing) can form a conductive structure 274 through the insulation material 228 in the signal trench 224 that is coupled to the bond pad 260, thereby interconnecting the first and second wafers 210, 250. In some embodiments, the conductive structure is a high aspect ratio (HAR) contact structure that can include Tungsten, copper, and/or any other suitable conductive material.

As further illustrated in FIG. 2I, the BEOL processing stages can form (or place) a third wafer 270 over the first side 211a of the first wafer 210. For example, the BEOL processing stages can include one or more deposition stages, etching stages, and/or plating stages to form metallization layers 272, the conductive structure 274, and/or one or more bond pads 276 (one illustrated in FIG. 2I). The gate 220 of the first wafer 210 can be coupled to one or more of the metallization layers 272 to receive and route signals within the device 200. Similarly, the conductive structure 274 can be coupled between the bond pad 260 of the second wafer 250 and one or more of the metallization layers 272 to further route signals within the device 200. In turn, the bond pad 276 (sometimes also referred to herein as a “package interconnect,” a “package terminal,” and/or the like) can electrically couple one or more of the metallization layers 272 to an external component, such as another device, a controller, a package substrate, and/or the like to receive and route signals external to the device 200.

In some embodiments, the third wafer 270 can be an interposer substrate premanufactured with the metallization layers 272, the conductive structure 274, and/or the bond pad 276. In such embodiments, the BEOL processing can include attaching the interposer substrate to the first side 211a of the first wafer 210. Further, in some such embodiments, the manufacturing process uses the first alignment feature 230 to position the third wafer 270 before bonding the third wafer 270 to the first wafer 210.

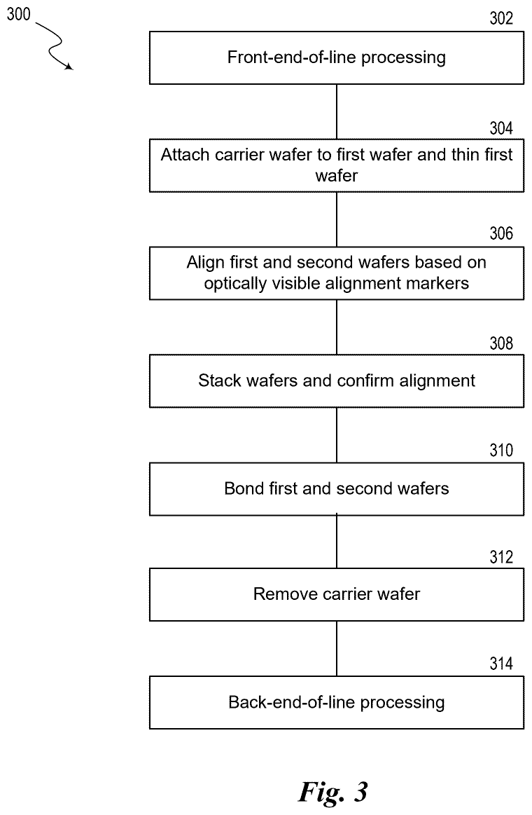

FIG. 3 is a flow diagram of a process 300 for manufacturing semiconductor devices in accordance with some embodiments of the present technology. In the illustrated embodiment, the process 300 begins at block 302 with FEOL processing on one or more first wafers. An example of a result of the FEOL processing at block 302 is illustrated in FIG. 2A.

At block 304, the process 300 includes attaching a front side of the first wafer to a carrier wafer and thinning a back side of the first wafer. As discussed above, the thinning process can include a mechanical grinding process, a CMP process, a dry etch process, a wet etching process, and/or any other suitable process to remove material from the back side of the first wafer. The thinning process both reduces the footprint of the first wafer and exposes one or more structures (e.g., signal trenches, alignment features, bond pads, and/or the like) at the back side of the first wafer (e.g., as illustrated in FIG. 2C).

It will be understood that, in some embodiments, the process 300 can omit one or more of the steps discussed above with reference to block 302 and 304. Purely by way of example, the FEOL processing can be completed at the wafer level by a separate process (and/or in a separate facility). In such embodiments, the process 300 begins at block 304 by attaching a pre-manufactured first wafer to a carrier wafer. In another example, each of the processes discussed above can be completed during a pre-manufacturing stage and the process 300 can begin by providing a thinned first wafer attached to a carrier wafer and proceed to block 306.

At block 306, the process 300 includes aligning the back side of the first wafer with a front side of a second wafer based on optically visible alignment features. As discussed above with reference to FIGS. 2D and 2E, the alignment feature on the first wafer can include an alignment mark formed at the front side of the first wafer and visible through a transparent (or semitransparent) material (e.g., an oxide-filled trench). As also discussed above, the alignment feature on the second wafer can include one or more alignment marks formed on the front surface of the second wafer. In some embodiments, the alignment at block 306 includes measuring and/or recording a location of the alignment mark on the first wafer via an optical measurement, measuring and/or recording a location of the alignment mark(s) on the second wafer via an optical measurement, and positioning the first wafer over the second wafer based on the measured and/or recorded locations. In some embodiments, the carrier wafer includes a window (e.g., a through-substrate trench filled with an oxide material) that is generally aligned with the alignment feature on the first wafer. The window allows the alignment at block 306 to be completed using an optical tool looking through the carrier wafer and the alignment feature on the first wafer (e.g., resulting in a view similar to FIG. 2G). In all embodiments, the optical measurements can provide an increase in accuracy over alignments based on infrared images of the alignment features on the first wafer. The increase in accuracy can be based on the lack of scattering and/or loss of image focus when optically identifying the alignment features on the first wafer as compared to an infrared image is taken through the base substrate and the carrier wafer.

At block 308, the process 300 includes stacking the first and second wafers and confirming the alignment. In some embodiments, confirming the alignment can include imaging the stacked wafers through the carrier wafer using an infrared device. The infrared device can obtain an image similar to the view illustrated in FIG. 2G in less focus (e.g., with fuzzy edges based on the limitations of the infrared device). In some embodiments, the process 300 uses a first set of alignment features to initially align and stack the wafers and a second set of alignment features to confirm the alignment at block 308. In such embodiments, the first set of alignment features can have a first alignment pattern that is especially when using optical imaging techniques (e.g., uses relatively small shapes that provide an increase in accuracy that would not be visible with infrared measurements) while the second set of alignment features can have a second alignment pattern that is better suited for use with the infrared imaging system (e.g., does not require shapes to overlap, uses relatively large shapes, and/or the like). In some embodiments, confirming the alignment includes optically verifying the alignment through the carrier wafer (e.g., when the carrier wafer includes a window).

At block 310, the process 300 includes bonding the first and second wafers together. As discussed above, the bonding process can include forming various metal-metal bonds, substrate-substrate bonds, hybrid bonds, one or more annealing processes, one or more reflow processes, and/or any other suitable process.

At block 312, after bonding the first and second wafers, the carrier wafer can be removed from the first wafer. A result of the process 300 at block 312 is illustrated in FIG. 2H. In some embodiments, the process 300 completes after block 312 and returns to block 302 (or block 304 or block 306) to produce additional devices). For example, the process 300 can produce a wafer ready for BEOL processing as part of another manufacturing process and/or for inclusion into another suitable semiconductor structure (e.g., a die stack without the BEOL structures between dies). In other embodiments, the process 300 continues to block 314.

At block 314, the process 300 includes performing various BEOL processes (and/or various MOL processes), a result of which is illustrated in FIG. 2I. In various embodiments, the BEOL processing can include depositing one or more layers of a substrate, one or more insulating layers, and/or metallization layers; etching any of the deposited layers and/or filling any etched vias, trenches, and/or holes; forming one or more external bond pads; and/or any other suitable process. Additionally, or alternatively, the BEOL processing can include attaching a premanufactured interposer substrate to the front side of the first wafer.

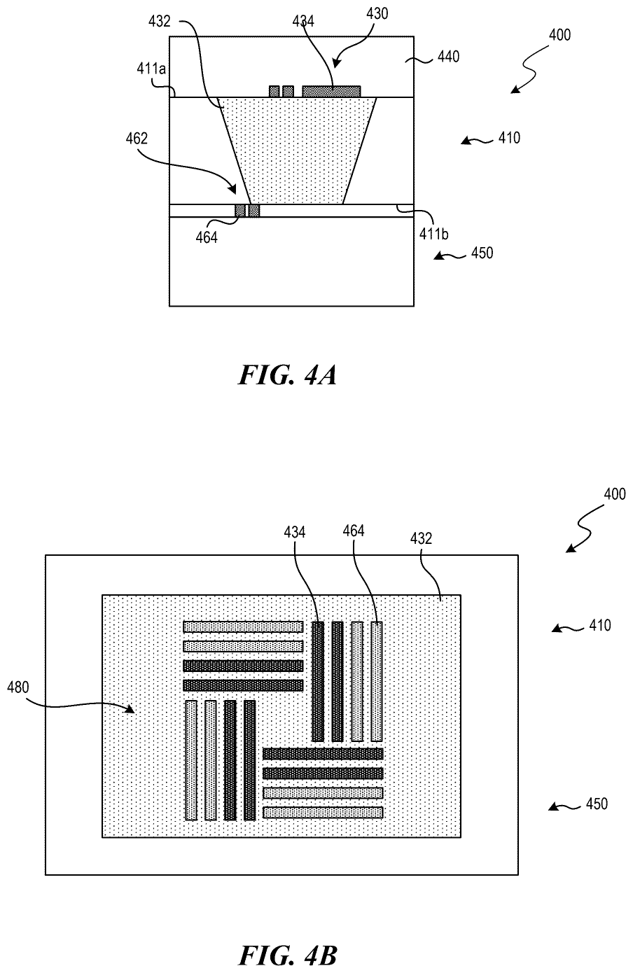

Various additional details and embodiments of alignment features in accordance with further embodiments of the present technology are discussed below with reference to FIGS. 4A-7B. The alignment features in each of the embodiments below can be in place of, or in addition to, the alignment features discussed above with reference to FIGS. 2A-2I to help optically align wafers during semiconductor manufacturing.

FIGS. 4A and 4B are a partially schematic cross-sectional view and a partially schematic top view, respectively, of a semiconductor device 400 in accordance with further embodiments of the present technology. As illustrated in FIG. 4A, the semiconductor device 400 (“device 400”) can be generally similar to the device 200 discussed above with reference to FIGS. 2A-2I. For example, the device 400 includes a first wafer 410, a carrier wafer 440 attached to a first side 411a (e.g., a front side) of the first wafer 410, and a second wafer 450 attached to a second side 411b (e.g., a back side) of the first wafer 410. Further, the first wafer 410 includes a first alignment feature 430 (sometimes also referred to as an “alignment trench”) that includes a generally transparent material 432 (“transparent material 432”) and first alignment marks 434 formed in the transparent material 432. Similarly, the second wafer 450 includes a second alignment feature 462 that includes second alignment marks 464.

As illustrated in FIG. 4B, however, the first and second alignment features 430, 462 include additional first and second alignment marks 434, 464 (e.g., compared to the first and second alignment features 230, 262 of FIGS. 2A-2I). When the first and second wafers 410, 450 are sufficiently aligned, the first and second alignment marks 434, 464 form a complex pattern 480 without overlap between the first and second alignment marks 434, 464. The complex pattern 480 can be useful for precise alignment of the first and second wafers 410, 450 that is made possible by the optical imaging of the first and second alignment features 430, 462 when bonding the wafers (e.g., as discussed with reference to FIG. 3).

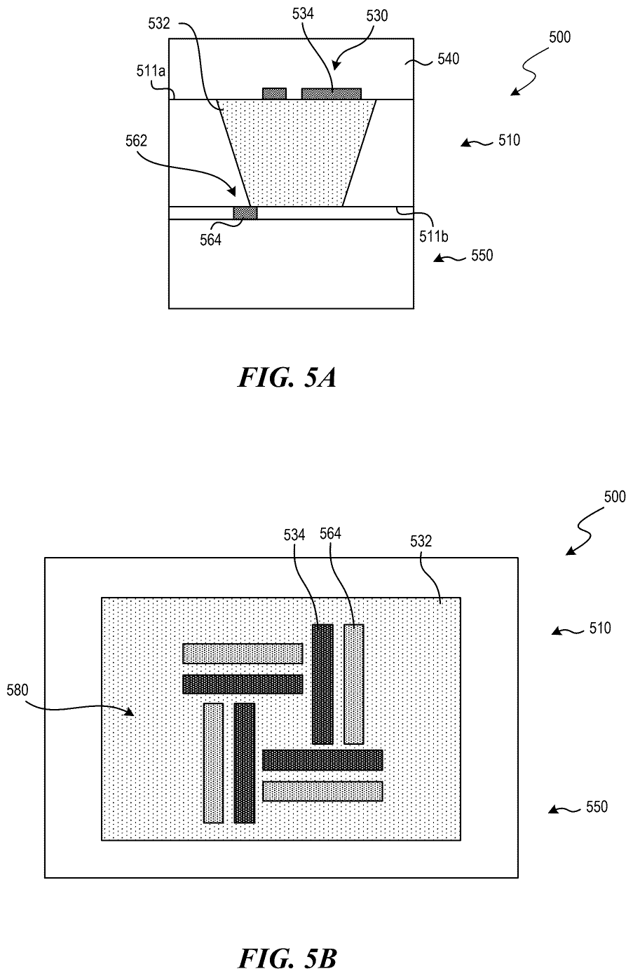

FIGS. 5A and 5B are a partially schematic cross-sectional view and a partially schematic top view, respectively, of a semiconductor device 500 configured in accordance with further embodiments of the present technology. As illustrated in FIG. 5A, the semiconductor device 500 (“device 500”) is generally similar to the device 400 discussed above with reference to FIGS. 4A and 4B. For example, the device 500 includes a first wafer 510, a carrier wafer 540 attached to a first side 511a (e.g., a front side) of the first wafer 510, and a second wafer 550 attached to a second side 511b (e.g., a back side) of the first wafer 510. Further, the first wafer 510 includes a first alignment feature 530 that has a plurality of first alignment marks 534 formed at the first side 511a and within a window (e.g., within a longitudinal footprint) of a generally transparent material 532. Similarly, the second wafer 550 includes a second alignment feature 562 that includes a plurality of second alignment features 564 formed within a window of the transparent material 532.

As illustrated in FIG. 4B, however, the first and second alignment marks 534, 564 are relatively large compared to the first and second alignment features 434, 464 of FIGS. 4A and 4B. As a result, the first and second alignment marks 534, 564 form an alignment pattern 580 (when the first and second wafers 510, 550 are sufficiently aligned) that can be more easily confirmed by an infrared imaging device. Accordingly, the alignment pattern 580 can be especially useful for confirming the alignment of the first and second wafers 510, 550 after they are stacked.

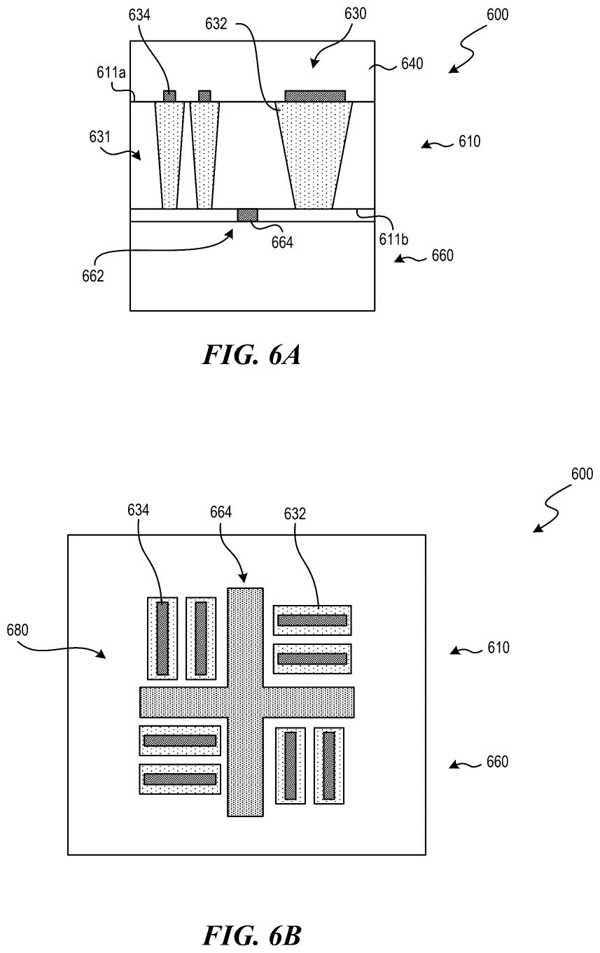

FIGS. 6A and 6B are a partially schematic cross-sectional view and a partially schematic top view, respectively, of a semiconductor device 600 configured in accordance with further embodiments of the present technology. As illustrated in FIG. 6A, the semiconductor device 600 (“device 600”) is generally similar to the devices 400, 500 discussed above with reference to FIGS. 4A-5B. For example, the device 600 includes a first wafer 610, a carrier wafer 640 attached to a first side 611a (e.g., a front side) of the first wafer 610, and a second wafer 650 attached to a second side 611b (e.g., a back side) of the first wafer 610. Further, the first wafer 610 includes a first alignment feature 630 while the second wafer 650 includes a second alignment feature 662. In the illustrated embodiment, however, the first alignment feature 630 includes a plurality of trenches 631 that are each filled with a generally transparent material 632 and include a first alignment mark 634. Further, the second alignment feature 662 includes a single second alignment mark 664 that is positioned out of vertical alignment with any of the trenches 631, but still within a longitudinal footprint of the first alignment feature 630.

As a result, as illustrated in FIG. 6B, when the first and second wafers 610, 650 are sufficiently aligned, the second alignment mark 664 is not visible in any of the windows from the transparent material 632 and/or does not overlap with any of the first alignment marks 634. Instead, as further illustrated in FIG. 6B, the windows from the transparent material 632 can frame an outline of the second alignment mark 664 to form an alignment pattern 680. When the second alignment mark 664 has a sufficiently complex shape (e.g., a plus sign in the illustrated embodiment), the absence of the second alignment mark 664 in any of the windows from the transparent material 632 guarantees that the first and second wafers 610, 650 are sufficiently aligned.

FIGS. 7A and 7B are a partially schematic cross-sectional view and a partially schematic top view, respectively, of a semiconductor device 700 configured in accordance with further embodiments of the present technology. As illustrated in FIG. 7A, the semiconductor device 700 (“device 700”) is generally similar to the device 600 discussed above with reference to FIGS. 6A and 6B. For example, the device 700 includes first and second wafers 710, 750 that include first and second alignment features 730, 762, respectively. Further, the first alignment feature 730 includes a plurality of trenches 731 that are each filled with a generally transparent material 732 (“transparent material 732”) and the second alignment feature 762 includes a single second alignment mark 764 that is positioned out of vertical alignment with any of the trenches 731 but within a longitudinal footprint of the first alignment feature 730. However, in the illustrated embodiment, the first alignment feature 730 does not include a first alignment mark positioned in the transparent material 732. Instead, the window from the transparent material 732 can be optically identified and used for to align of the first and second wafers 710, 750.

For example, as illustrated in FIG. 7B, when the first and second wafers 710, 750 are sufficiently aligned, the second alignment mark 764 is not visible in any of the windows from the transparent material 732. Instead, the windows from the transparent material 732 can frame an outline of the second alignment mark 764 to form an alignment pattern 780. In the embodiment illustrated in FIG. 7B, the absence of any first alignment marks can help simplify the analysis and/or remove a source of error (e.g., from lines corresponding to the first alignment marks). As a result, a manufacturing process using the embodiments of FIGS. 7A and 7B may be able to more easily confirm that the first and second wafers 710, 750 are sufficiently aligned after they are stacked. However, the identification of the windows of the transparent material 732, without the first alignment marks, can be more difficult.

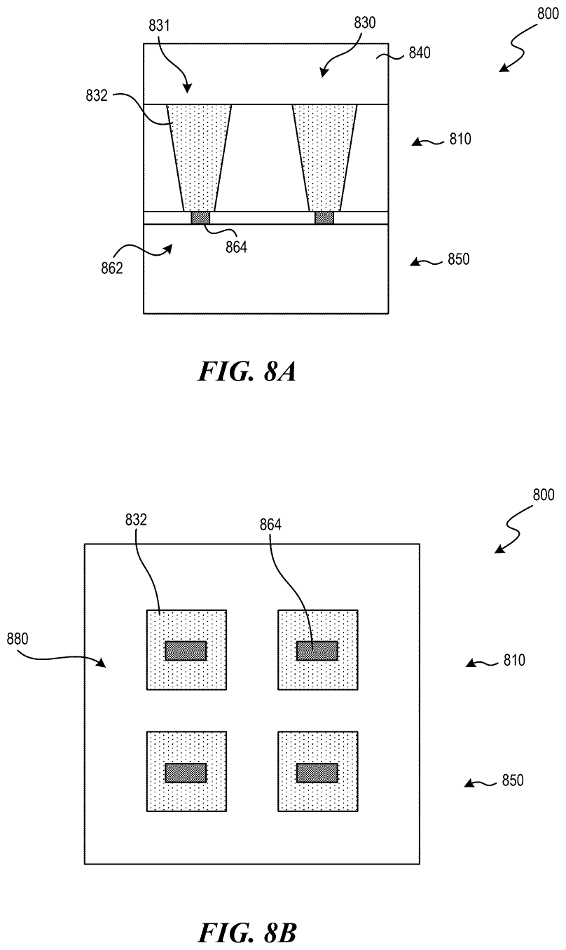

FIGS. 8A and 8B are a partially schematic cross-sectional view and a partially schematic top view, respectively, of a semiconductor device 800 configured in accordance with further embodiments of the present technology. As illustrated in FIG. 8A, the semiconductor device 800 (“device 800”) is generally similar to the device 700 discussed above with reference to FIGS. 7A and 7B. For example, the device 800 includes first and second wafers 810, 850 that include first and second alignment features 830, 862, respectively. Further, the first alignment feature 830 includes a plurality of trenches 831 that are each filled with a generally transparent material 832 (“transparent material 832”) and do not include a first alignment mark. In the illustrated embodiment, however, the second alignment feature 862 includes a plurality of second alignment marks 864 each corresponding to one of the plurality of trenches 831.

For example, as illustrated in FIG. 8B, when the first and second wafers 810, 850 are sufficiently aligned, at least one of the second alignment marks 864 is visible in each of the windows from the transparent material 832 to form an alignment pattern 880. Similar to the discussion above with reference to FIG. 7B, the absence of any first alignment marks in the windows from the transparent material 832 can help simplify the analysis and/or remove a source of error. As a result, a manufacturing process using the embodiments of FIGS. 8A and 8B may be able to more easily confirm that the first and second wafers 810, 850 are sufficiently aligned after they are stacked. Further, the visual confirmation from each of the second alignment marks 864 in the windows from the transparent material 832 can allow the embodiments of FIGS. 8A and 8B to be checked via an optical analysis (e.g., when the carrier wafer 840 (FIG. 8A) is transparent and/or includes a window).

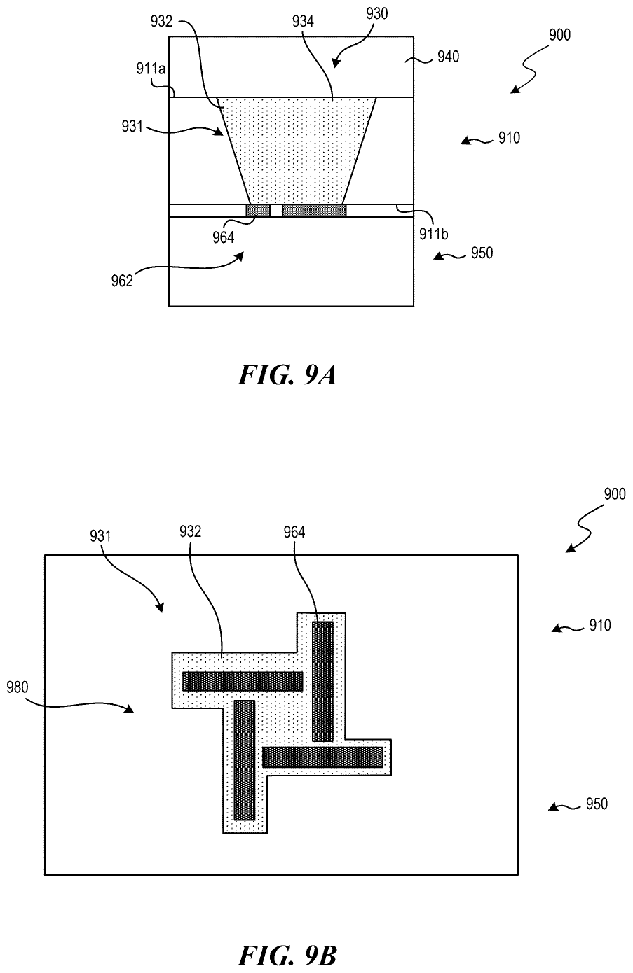

FIGS. 9A and 98B are a partially schematic cross-sectional view and a partially schematic top view, respectively, of a semiconductor device 900 configured in accordance with further embodiments of the present technology. As illustrated in FIG. 9A, the semiconductor device 900 (“device 900”) is generally similar to the device 800 discussed above with reference to FIGS. 8A and 8B. For example, the device 900 includes first and second wafers 910, 950 that include first and second alignment features 930, 962, respectively. Further, the first alignment feature 930 includes a trench 931 that is filled with a generally transparent material 932 (“transparent material 932”) and does not include a first alignment mark. Still further, the second alignment feature 962 includes a plurality of second alignment marks 964 within a window (e.g., footprint) of the trench 931.

As best illustrated in FIG. 9B, however, the trench 931 is formed with a shape (e.g., a windmill shape in the illustrated embodiment) that can mate with the second alignment marks 964 to form an alignment pattern 980 when the first and second wafers 810, 850 are sufficiently aligned. That is, in the illustrated embodiment, the shape of the trench 931 itself helps provide an indication of when the first and second wafers 810, 850 are aligned. Similar to the discussion above with reference to FIGS. 7B and 8B, the absence of any first alignment marks in the window with the transparent material 932 can help simplify the analysis and/or remove a source of error. As a result, a manufacturing process using the embodiments of FIGS. 9A and 9B may be able to more easily confirm that the first and second wafers 910, 950 are sufficiently aligned after they are stacked. Further, the relatively large window and shapes can provide enough detail, even in a blurry infrared image, to confirm the alignment of the first and second wafers 910, 950. As a result, it can be easier to confirm the alignment of the first and second wafers 910, 950 with the alignment pattern 980 than, for example, with the alignment pattern 880 illustrated ion FIG. 8B.

It will be understood that while various specific examples of alignment patterns, shapes of alignment features, and orientations of the alignment features have been discussed above, the technology is not limited to any of the specific patterns, shapes, orientations, and/or the like. Purely by way of example, the first and second alignment marks can form any number of alignment patterns when the first and second wafers are properly aligned. Further, a manufacturing process can use any number of combinations of the alignment features discussed above. For example, a manufacturing process may use a first set of alignment features similar to those discussed above with reference to FIGS. 4A and 4B when using an optical measurement to align and stack the wafers, then can use a second set of alignment features similar to those discussed above with reference to FIGS. 8A and 8B when using an infrared measurement to confirm the alignment. Still further, the technology disclosed herein is not limited to use in a two-wafer manufacturing process. Instead, any number of wafers can be stacked using alignment features similar to those discussed herein. Additionally, or alternatively, the alignment features discussed herein can be used to align and stack various other semiconductor components, such as semiconductor dies for a stacked die assembly. Accordingly, the technology disclosed herein is not to be limited to any of the specific embodiments illustrated and discussed above.

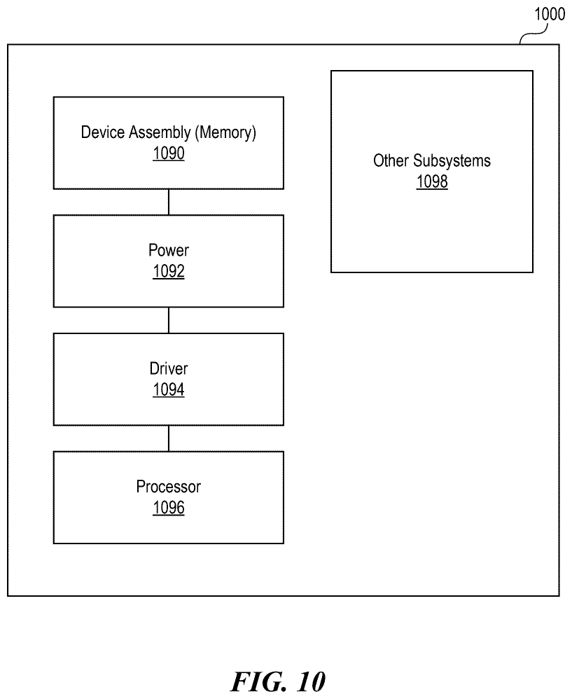

FIG. 10 is a schematic view of a system that includes a semiconductor die assembly configured in accordance with embodiments of the present technology. That is, the semiconductor device assemblies discussed above can be incorporated into any of a myriad of larger and/or more complex systems, a representative example of which is system 1000 shown schematically in FIG. 10. The system 1000 can include a memory 1090 (e.g., SRAM, DRAM, flash, and/or other memory devices), a power supply 1092, a drive 1094, a processor 1096, and/or other subsystems or components 1098. Semiconductor assemblies resulting from bonding processes of the type discussed above with reference to FIGS. 1-9B can be included in any of the elements shown in FIG. 10. Purely by way of example, a semiconductor device resulting from the wafer-to-wafer bonding process discussed with reference to FIGS. 2A-3 can be deployed in the memory 1090 (e.g., in a managed NAND for us in various consumer electronics, automotive electronics, and the like; an SSD package; and/or any other suitable memory device) to improve the alignment of the components therein and therefore the performance of the memory 1090.

The resulting system 1000 can be configured to perform any of a wide variety of suitable computing, processing, storage, sensing, imaging, and/or other functions. Accordingly, representative examples of the system 1000 include, without limitation, computers and/or other data processors, such as desktop computers, laptop computers, Internet appliances, hand-held devices (e.g., palm-top computers, wearable computers, cellular or mobile phones, automotive electronics, personal digital assistants, music players, etc.), tablets, multi-processor systems, processor-based or programmable consumer electronics, network computers, and minicomputers. Additional representative examples of the system 1000 include lights, cameras, vehicles, etc. With regard to these and other examples, the system 1000 can be housed in a single unit or distributed over multiple interconnected units, e.g., through a communication network. The components of the system 1000 can accordingly include local and/or remote memory storage devices and any of a wide variety of suitable computer-readable media.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally”, “approximately,” and “about” are used herein to mean within at least within 10 percent of a given value or limit. Purely by way of example, an approximate ratio means within ten percent of the given ratio.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A method for forming a semiconductor device, the method comprising:
attaching a first surface of a first wafer to a carrier wafer, wherein the first wafer includes a first alignment feature extending from the first surface to a second surface opposite the first surface;
optically measuring a first position of the first alignment feature of the first wafer;
optically measuring a second position of a second alignment feature on an upper surface of a second wafer;
aligning the first wafer over the second wafer with the first alignment feature vertically aligned with the second alignment feature based on the measured first and second positions;
stacking the first wafer on the second wafer such that the second surface of the first wafer contacts the upper surface of the second wafer; and
bonding the first and second wafers together.

2. The method of claim 1 wherein optically measuring the first position of the first alignment feature comprises imaging a lower surface of the first alignment feature exposed on the second surface of the first wafer.

3. The method of claim 1 wherein the first alignment feature includes a transparent material extending from the first surface to the second surface and an alignment mark at the second surface, and wherein optically measuring the first position of the first alignment feature comprises optically identifying the alignment mark through the transparent material.

4. The method of claim 1, further comprising confirming an alignment of the first and second wafers before bonding the first and second wafers together.

5. The method of claim 4 wherein confirming the alignment of the first and second wafers comprises measuring, using an infrared imaging device, a position of the first and second alignment features.

6. The method of claim 4 wherein the first and second alignment features are a first pair of alignment features, and wherein confirming the alignment of the first and second wafers comprises imaging a second pair of alignment features independent from the first pair of alignment features.

7. The method of claim 4 wherein confirming the alignment of the first and second wafers comprises confirming the first and second alignment features are vertically aligned to form an alignment pattern.

8. The method of claim 1 wherein the first wafer further includes a conductive structure formed in a signal trench extending from the first surface to the second surface, wherein the second wafer further includes a bond pad at the upper surface, and wherein aligning the first wafer over the second wafer further includes vertically aligning the signal trench of the first wafer with the bond pad on the upper surface of the second wafer.

9. The method of claim 1 wherein the first wafer further includes a conductive structure extending from the first surface to the second surface, and wherein the method further comprises:
removing the carrier wafer from the first surface of the first wafer; and
forming one or more metallization layers over the first surface of the first wafer, wherein the conductive structure is electrically coupled to at least one of the one or more metallization layers.

10. A semiconductor device, comprising:
a first wafer, comprising:
a front surface and a back surface opposite the front surface;
one or more through signal trenches extending from the front surface to the back surface, wherein each of the one or more signal trenches includes a conductive structure; and
one or more first alignment features each comprising a transparent material extending from the front surface to the back surface forming one or more windows between the front surface and the back surface, wherein each of the one or more first alignment features has a longitudinal footprint; and
a second wafer, comprising:
an upper surface coupled to the back surface of the first wafer;
one or more conductive pads formed on the upper surface, wherein each of the one or more conductive pads is electrically coupled to the conductive structure in a corresponding one of the one or more signal trenches; and
one or more second alignment features positioned within the longitudinal footprint of a corresponding one of the one or more first alignment features.

11. The semiconductor device of claim 10 wherein each of the one or more first alignment features includes one or more first alignment marks, wherein each of the one or more second alignment features includes one or more second alignment marks, and wherein the one or more first alignment marks and the one or more second alignment marks do not vertically overlap.

12. The semiconductor device of claim 10 wherein each of the one or more second alignment features includes one or more alignment marks that are visible in the one or more windows of the corresponding one of the one or more first alignment features.

13. The semiconductor device of claim 10 wherein each of the one or more second alignment features includes one or more alignment marks that are not vertically aligned with the one or more windows of the corresponding one of the one or more first alignment features.

14. The semiconductor device of claim 10 wherein the transparent material is an oxide-based material.

15. The semiconductor device of claim 10, further comprising a third wafer coupled to the front surface of the first wafer, wherein the third wafer comprises one or more metallization layers, and wherein each of the conductive structures in the one or more signal trenches in the first wafer is electrically coupled to one or more of the one or more metallization layers in the third wafer.

16. The semiconductor device of claim 10 wherein each of the one or more signal trenches includes an insulation material formed around the conductive structure, and wherein the transparent material is the same as the insulation material.

17. A method of manufacturing a semiconductor device, the method comprising:
forming one or more signal trenches and a first alignment feature in a first surface of a first wafer;
attaching the first surface of the first wafer to a carrier wafer;
removing material from a second surface of the first wafer to thin the first wafer and expose a first lower surface of at least one of the one or more signal trenches and a second lower surface of the first alignment feature;
aligning the first alignment feature on the first wafer with a second alignment feature on a second wafer, wherein the second wafer includes an upper surface and at least one conductive pad at the upper surface corresponding to each of the one or more signal trenches exposed on the second surface of the first wafer; and
stacking the second surface of the first wafer on the upper surface of the second wafer.

18. The method of claim 17 wherein forming the one or more signal trenches and the first alignment feature comprises:
forming a first trench in the first surface of the first wafer to an intermediate depth;
forming a second trench in the first surface of the first wafer spaced to the intermediate depth, wherein the second trench is spaced apart from the first trench by a known distance; and
filling the first and second trenches with an oxide-based material.

19. The method of claim 17 wherein the first alignment feature includes an alignment marker at the first surface of the first wafer, and wherein aligning the first alignment feature with the second alignment feature includes optically imaging the alignment marker through the second lower surface of the first alignment feature.

20. The method of claim 17 wherein aligning the first alignment feature with the second alignment feature includes optically imaging the second lower surface of the first alignment feature to identify a location of the first alignment feature from the second surface of the first wafer.
